(19) United States
(12) Patent Application Publication
(10) Pub. No.: US 2020/0098817 A1
(43) Pub. Date: Mar. 26, 2020

(54) SOLID-STATE STREAK CAMERA

(71) Applicant: Mission Support and Test Services, LLC, Las Vegas, NV (US)

(72) Inventors: Yekaterina Opachich, Livermore, CA (US); John Larry Porter, JR., Livermore, CA (US); Lawrence MacNeil, Livermore, CA (US)

(21) Appl. No.: 16/138,890

(22) Filed: Sep. 21, 2018

(51) Int. Cl. H01L 27/146

(52) U.S. Cl. CPC H01L 27/14643; H01L 27/14609; H01L 27/14636

(57) ABSTRACT

A solid-state streak camera having photodetectors configured to receive energy from an event and convert the energy to an electrical signal. The electrical signal is presented on a conductive path that has two or more capacitors spaced along the conductive path, the capacitors configure to accept and hold capacitor charge. The capacitor charge represents the energy from the event received by the photodetectors and the location of the capacitors along the conductive path correlates to time of the receipt of the energy on the photodetector. Analog to digital converters convert the capacitor charge to digital values and a memory stores the digital values as data associated with the photodetector that generated the data. Reliable and constant results or obtained and high resolution may be obtained with a two-dimensional photodetector array.

### 1. STATEMENT REGARDING FEDERAL RIGHTS

This invention was made with government support under Contract No. DE-AC52-06NA25946 and was awarded by the U.S. Department of Energy, National Nuclear Security Administration. The government has certain rights in the invention.

### 2. FIELD OF THE INVENTION

The innovation relates to streak cameras and, in particular, to solid-state streak camera and method of operation.

### 3. RELATED ART

Streak cameras are an essential diagnostic tool used in shock physics and high energy density physics experiments. Among these are shock physics and high energy density experiments which require reproducible spatial and temporal detector performance under extreme conditions. Such experiments require well calibrated temporally resolving diagnostics for studying events that occur on the nanosecond to microsecond time scales. Although analog (tube-based) streak cameras are in common use with in the scientific community, they require routine calibration and typically lack reproducibility.

The detector efficiency of streak cameras is highly dependent on the wavelength range, and photocathode material used, with typical quantum efficiency ranging anywhere from 0.1% for X-ray detection, to 30% in the IR region. These low detector efficiencies limit the quality of data obtained. The spatial resolution of vacuum based streak cameras is limited by space charge and electron optics, both degrade the performance of the detector. One disadvantage of prior art streak cameras is that these detectors are large in size and difficult to incorporate into experiments and require routine calibration and characterization. A further drawback of prior art streak camera detectors is that the cost of replacement cameras and maintenance is high, and due to the fragile nature of prior art tube based streak cameras, replacement due to damage was not uncommon.

FIG. 1 illustrates a generalized diagram of a prior art streak camera. As shown an energy source directs energy 108 to a slit 112. The energy 108 may be photons. In some embodiments the camera may be angled such that the photons strike an inner wall or block. The slit plate 112 allows only a select portion of the photons to pass and may be aligned with an active region of a photocathode, located directly behind the slit plate and also aligned with other components of the streak camera. Exiting the slit plate 112 are electrons 114 which are created by incident radiation upon the photocathode 113. The photocathode 113 emits electrons 114 that pass between two charged plates 116 and through a focusing lens 120 (either magnetic or electro static), which focuses, directs or sweeps the electrons toward and across imaging detector 124, such as a phosphor plate causing the imaging detector to illuminate. This illumination can be viewed and recorded with traditional optical recording devices. The focusing lens 120 may be any type of lens capable of focusing electrons, including but not limited to electrostatic or magnetic.

In operation, streak cameras record temporal information of dynamic phenomenon over a given time window, which is typically a very short time window. The components of a streak camera are shown in FIG. 1. In operation, an incident photon impulse is directed to the slit plate 112 where it is limited spatially one dimension (1-D) with a slit. The photocathode 113 is used to convert photons to electrons which are then extracted and accelerated with a strong electric field within a vacuum tube 110. The vacuum tube 110, which may vary in shape, contains the cathode 113, slit 112, mesh sweep plates 116, focusing lens 120 and imaging detector 124. The electron signal is temporally dispersed with a set of voltage ramps applied to two parallel “sweep” plates 116, and focused by the focusing lens 120, onto an imaging detector 124, such as a phosphor screen. The resulting image on the imaging detector 124 provides a time varying profile of the incident impulse as a function of position along the slit in the slit plate 112.

Because the prior art relied on vacuum tube technology it utilized a large detector and had a limited useable data region on the imaging detector, which limited accuracy of data evaluation. This is due to the varying focusing profile generated by the focusing optics. In addition, the vacuum tube technology device was often not consistent from one experiment to the next. Failure to maintain consistence over repeated experiments resulted in data that may have varied due to changes in the experiment or simply due to inconsistences in the vacuum tube based streak camera. In addition, the plates and tube in prior art streak camera required high voltages for operation. These voltages can range between 100s to 10000 volts, which create numerous challenges and safety issues.

The limitations of prior art vacuum tube technology have been reached and improvement will not be achieved without significant investment of additional time and money. These limitations include expense and it is difficult to achieve further improvements in speed and capability. Furthermore, inconsistences exist between multiple detector units which can lead to inconsistent data samples collected from the same event.

The innovation disclosed below overcomes the drawbacks of the prior art and provides additional advantages.

### SUMMARY

To overcome the drawbacks of the prior art and provide additional benefits, disclosed is a solid-state streak camera. In one embodiment, the solid-state streak camera comprises a photodetector array that includes one or more photodetectors that are configured to detect energy such as incident radiation on the photodetector and generate an electrical signal responsive thereto. Also part of this embodiment is a sample cell module (capacitor array) that is configured to receive and sample the electrical signal as the electrical signal is on the conductive path to create sample values. The sample cell module may also be referred to as a switched capacitor array (or capacitor array). Analog to digital converters are configured to convert the sample values to digital sample values and a memory is configured to store the digital sample values as data such that the data represents the energy or incident radiation on the photodetector. It is also contemplated that the energy or detection could comprise neutrons through direct or indirect detection. In addition, the detection could be of a high energy event that is not directly observable. For example, the detector, photodetectors in this embodiment, do not need to be directly exposed to the energy, it could be translated through a scintillator, either fibers or a plate.

In one embodiment, the radiation is from one of the following energy (photon energy) types: photons, x-rays, UV or infrared rays. The array may be one-dimensional or two-dimensional. In one configuration, the sample cell module comprises a conductive path with capacitors spaced along the conductive path at connection points and the capacitors are configured to store the charge existing on the conductive path at the connection points. The data may be stored as a data array that relates in size and dimension to the photodetector array. In one configuration, the sample values captured from the electrical signal on the conductive path represent energy such as incident radiation or energy interactions on the photodetector over time. In one embodiment, the photodetectors comprise photodiodes.

Also disclosed is a solid-state streak camera that has photodetectors configured to receive energy from an event and convert the energy to an electrical signal. The electrical signal is provided to a conductive path that is configured to receive the electrical signal. Two or more capacitors are spaced along the conductive path such that the capacitors are configured to accept and hold capacitor charge. The capacitor charge represents the energy from the event received by the photodetectors and the location of the capacitors along the conductive path correlates to time of the receipt of the energy on the photodetector. Also part of this embodiment is an analog to digital converter configured to convert the capacitor charge on the capacitors to digital values that represent the energy received by the photodetectors over time at that location on the conductive path. A memory stores the digital values as data such that the data is associated with the photodetector that generated the data. Each photodetector may have this configuration to capture the charge over time for that particular photodetector.

In one embodiment, the energy is one of the following energy types: photons, x-rays, or infrared rays. As discussed herein, the photodetectors may be arranged as a two-dimensional array or a one-dimensional array. It is further contemplated that the one or more switches may be associated with the capacitors to selectively connect and disconnect the capacitor from the conductive path. The data that is stored as a data array may relate to or be the same dimension as the arrangement of the photodetectors. The photodetectors may comprise photodiodes.

Also disclosed is a method for detecting and recording energy levels, over time, from an event. In one embodiment, the method comprises positioning a photodetector array to receive energy from an event, such that the photodetector array is formed from photodetectors, and then receiving energy at the photodetectors that form the photodetector array. For photodetectors receiving energy, converting the energy received during a time period to a corresponding electrical signal which represents the energy received over time. Then, presenting the electrical signal on a conductive path, the conductive path having a first end and a second end with capacitors connected along the conductive path. The capacitors are configured to capture a charge value representing the electrical charge or signal magnitude at the capacitor's points of connection to the conductive path. This method of operation thus captures the charge value on the conductive path such that the position of the capacitor on the conductive path relates to or indicates the time at which the energy was received at the photodetector. Then, this method converts the charge value on the capacitors to digital values and stores the digital values in a memory.

The photodetectors may be photodiodes and the energy may be one of following types of energy: photons, x-rays, infrared. The photodetector array may form a two-dimensional array. The method may also include selectively connecting and disconnecting the capacitor from the conductive path with one or more switches.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 is a block diagram of a prior art streak camera.

FIG. 2 illustrates a generalized block of a solid-state streak camera.

FIG. 3 illustrates a block diagram of a one-dimensional photodiode array in combination with sample cells and processor.

FIG. 4 illustrates a block diagram of the analog interface and processor.

FIG. 5A illustrates an example embodiment of an analog input signal path with associated capacitors attached along the signal path.

FIG. 5B illustrates an alternative embodiment of a signal path with associated capacitors attached along the signal path having an output for digital conversion.

FIG. 6A illustrates a generalized diagram of a solid-state streak camera and the resulting data.

FIG. 6B illustrates an exemplary two-dimensional photodiode array with associated read-out circuit.

FIG. 7 illustrates an example flow diagram of an example method of operation.

FIG. 8 is a schematic of a computing or mobile device such as one of the devices described above, according to one exemplary embodiment.

### DETAILED DESCRIPTION

To overcome the drawbacks of the prior art and provide further advantages a solid-state streak camera is disclosed. In one embodiment, the proposed solid-state streak camera utilizes a one-dimensional photodiode array in place of the slit and cathode of prior art streak cameras. Each photodiode would represent a spatial resolution element set by the photodiode size and pitch. The diodes produce current generated by the incident photon impulse that is continuously sampled by the switched capacitor array within the fast sampling chip. The chip is clocked to lock in and readout charge from the capacitors, which is then displayed for each photodiode position. Such a device would collect time varying information as a function of position, identical to what is recorded with a streak camera detector. In addition, it will be possible to extend this concept to 2-D, with improvements to current photodiode array designs, and continual maturity of sampling chips needed for such a technology. Current off-the-shelf sampling chips can easily be daisy-chained to provide long time windows and scaled to accommodate many more photodiodes.

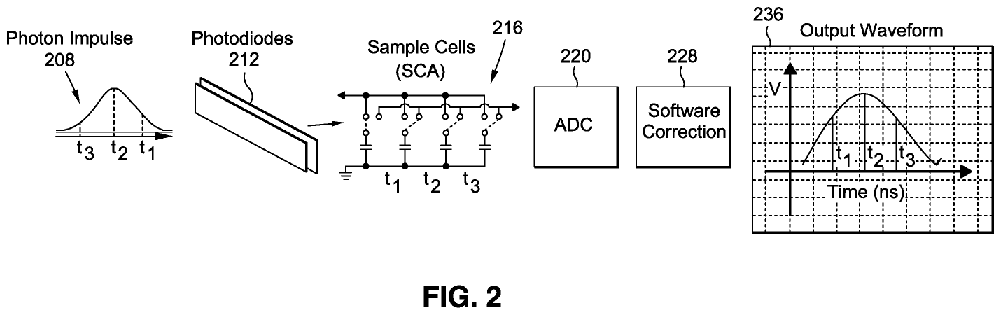

FIG. 2 illustrates a generalized block of a solid-state streak camera. This is but one example embodiment, and it is contemplated that other configurations are possible without departing from the claims. In this example, a photon stream with varying intensity over time T1 to T3 is directed to a photodiode array 212. The photodiode array receives the photons (or any other form of energy) and converts the photon interactions to electrical signals. Each photodiode generates an electrical signal which is provided to an associated conductive path with associated capacitors, which is collectively referred to herein as sample cells 216 or a domino circuit. The sample cells associated with each photodiode's conductive path includes a plurality of capacitors which are selectively connected to the signal path that conducts the electrical signal from the photodiode. The output of the sample cells 216 connect to an analog to digital (A/D) converter 220. The output of the A/D converter 220 is provided to a processor 228 configured to execute machine executable code to perform software correction on the digital data from the A/D converter 220. The resulting information from the processor may be presented as numeric data or graphical data 236. The graphical data 236 represents the photon pulse with high accuracy and consistency over time. As a benefit over the prior art the use of the array, such as array of photodiodes 212, is configured to record physical-location information regarding where the photon strikes occur while the sample cells (capacitors) record time resolved information at each particular location. Thus, for a 1-dimensional array, 2-dimensional information is obtained (location and time data).

Although shown as photons, it is contemplated that the impulse may comprise any energetic particle type including but not limited to neutrons, X-rays and visible light energy.

The photodiodes may comprise any type photodetector capable of converting an energy signal to a corresponding electrical signal. Any type fabrication technique or technology may be used to configure and tailor the photodiodes to react to the particular type of received energy, such a visible light, x-rays, photons, infrared or ultraviolet light. It is also contemplated that the diode arrays may exist, each tailored for a different type of energy and that these diode arrays may be swapped or changed to match the radiation type that is to be measured. Hence, one diode array is configured with diodes that detect x-ray signals while another diode array is configured to detect neutrons, and another diode array is configured to detect IR (infrared) or visible wavelengths. These different arrays may be swapped into and out of the system.

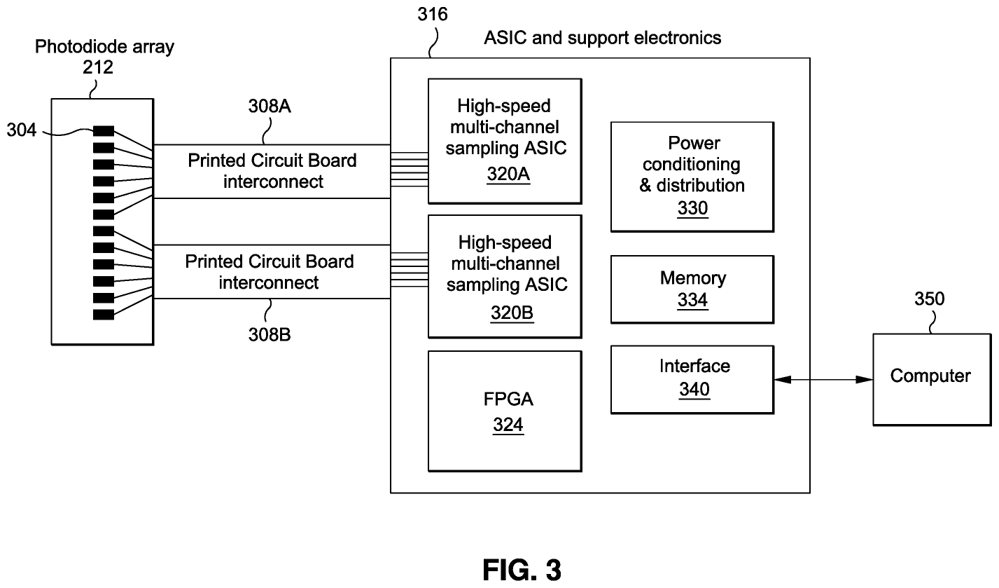

FIG. 3 illustrates a block diagram of a one-dimensional photodiode array in combination with sample cells and processor. This is but one possible arrangement of components and one of ordinary skill in the art may arrive at other embodiments without departing from the scope of the innovation. In this example embodiment, the photodiode array 212 is positioned to receive photons or other energy. Interconnects 308A, 308B electrically connect to the photodiode 304 of the photodiode array 212 to a circuit board 316. The circuit board includes numerous integrated circuits configured to process the electrical signals from the photodiode array 212. The interconnects between the diodes and the other electronics of the system can be extended such that the electronics are remote and/or shielded from the ionizing radiation or other harmful energy that strikes the diodes.

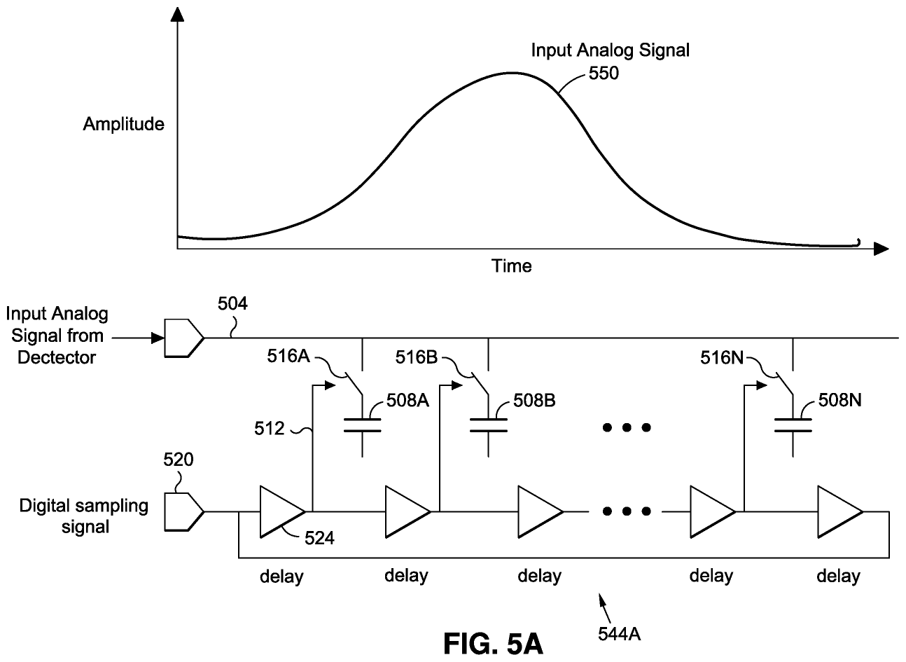

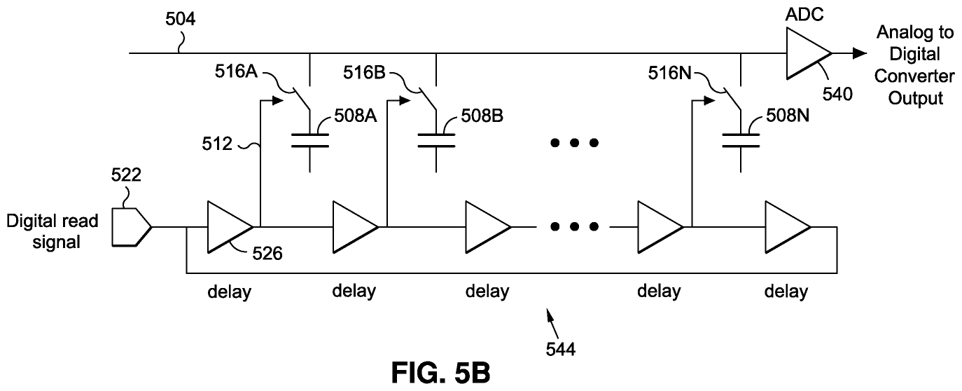

In this embodiment, the circuit board includes a first high speed multichannel sampling ASIC 320A, and a second high-speed multichannel sampling ASIC 320B. The first and second high speed multichannel sampling ASIC 320A, 320B electrically connect to the interconnects 308A, 308B and receive the electrical signals from the photodiodes 304. The high speed multichannel sampling ASIC 320A, 320B perform sampling of the electrical signals and convert the sampled electrical signals from an analog format into a digital format. In one example configuration, the high speed multichannel sampling ASIC 320A, 320B include a switched capacitor array with associated registers and analog to digital converters. The switched capacitor array is shown in greater detail in FIGS. 5 & 6A. In one embodiment the high speed multichannel sampling ASIC 320A, 320B comprises a PSEC4 device which is an application specific integrated circuit configured for high speed sampling of an electrical signal passing along a conductive path through use of a number of capacitors and high-speed capacitor charge sampling. The PSEC4 device is made by and selectively available from the University of Chicago. The PSEC4 device is described in a number of papers and generally understood in the art. As such, the PSEC4 device is not described in detail herein.

Also part of the circuit board is a processor 324, such as a field programmable gate array. In other embodiments, the processor may comprise any type processor of executing machine readable (executable) code to process the digital data from the high speed multichannel sampling ASICs 320A, 320B. Any type or brand of processor might be used, or control logic, or any other type device. In one embodiment, the array in the present innovation is on a single ASIC but in other embodiment, devices other than an ASIC or more than one ASIC may be used. The processor 324 communicates with the memory 334 for data storage and to read and execute machine readable code, also known as machine executable code, that is stored on the memory. A power conditioning and distribution unit 330 provides power at the proper voltage and current levels for the various components. Power may also be provided to the photodiode array 212. The power may be from a constant source such as a power grid or from a battery.

An interface 340 is also provided on the circuit board 316 and is configured to output the data from the circuit board to an external memory or display. Also part of the interface 340 is communicability with an external device, such as a computer or other controller to allow user input and control over the system. In one embodiment, the data from the photodiodes 304 is output to the computer 350 for storage as digital data.

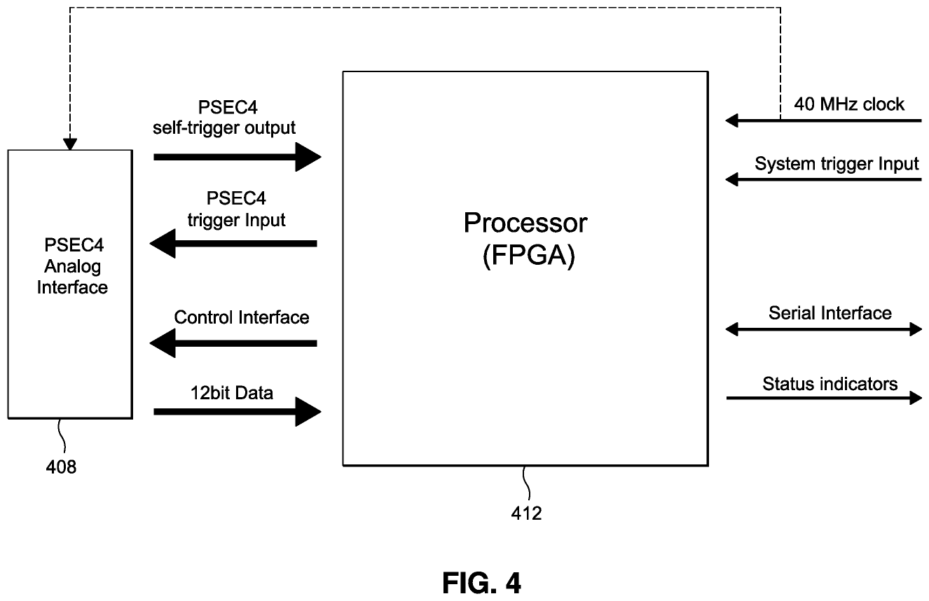

FIG. 4 illustrates a block diagram of the analog interface and processor. The analog interface 408, such as a PSEC4, receives the data from the photodiode array (not shown). The interface with the processor 412 includes a self-trigger output, a trigger input, a control interface, and a 12-bit data path. In other embodiments, any bit depth may be implemented. A clock signal, in this case a 40 MHz clock, is provided to both the processor 412 and the analog interface 408. In other embodiments, the clock frequency or sampling frequency may be greater than or less than 40 MHz. The analog interface may also comprise a DSR4 device (domino ring sampler).

The processor 412 receives various input signals. In this embodiment, the input signals are the clock and a system trigger input, which provides the signal to initiate operation. This signal may be linked to the event that generates the energy (incident radiation) which impacts the photodiodes. Other data inputs/outputs from the processor 412 include a serial interface, which communicates with the external computing device, and status indicators.

FIGS. 5A and 5B illustrate an example embodiment of a signal path (conductive path) with associated capacitors attached along the signal path. At the top of FIG. 5A is an example electrical signal from a photodiode. The horizontal axis represents time while the vertical axis represents magnitude. As can be seen, the magnitude of the signal varies with time. The goal is to capture the behavior of this signal and characterize it with digital data. The rise and fall in the electrical signal 550 occurs at a very high rate of speed. The electrical signal 550 travels on conductor 504 (signal path).

As shown in FIG. 5A, branched off the conductor 504 are numerous capacitors 508A, 508B up to 508N where N is any whole number. As the signal passes through the conductor 504 the charge on the capacitors vary in direct proportion to the amplitude of the input signal. An ADC can be connected to the input signal conductor as with a standard digitizer, but for this application it is usually isolated during sampling and utilized during read-off. Switches 516 are located between the conductor and the capacitors 508. The switches 516 are controlled by a switch control signal 512 which originates from a delay line 544 comprised of delays 524 as shown. A digital sampling signal 520 is presented to the delay line 544. This signal propagates through the delay line, which in turn provides the sequential switch control signals 512 at an effective sampled rate to the switches 516. As a result, the capacitors sample and hold (capture), at high speed, the signal 550 at specific, sequentially delayed times as the signal propagates through the conductor 504. The charge may be sampled at one speed while being read out at a different speed. As shown in FIG. 5B, a signal 522 is presented to a similar sequential delay line 544 so the captured capacitor values are then read-off the capacitors at the same or different rate using sequential delays 526, allowing similar or slower conversion than the fast input sampled rate, which permits higher resolution analog to digital conversion (ADC) at lower cost. The switched read-off lines connect to one (single-sequential) or more (banked) analog to digital converters 540 associated with this circuit to read off the capacitor values, which may also occur in association with the switches 516 selectively connecting the capacitors to the conductor 504 which may be the same or a separate read-off conductor from the sampling conductor, and is isolated from the outside signal input during read-off. The resulting digital data is provided to memory or a processor. Each detector element may have a circuit, such as shown in FIG. 5A and FIG. 5B, associated with it to read and record the electrical signal from the detector. The reading and writing of systems may be synchronous or asynchronous. It is contemplated that the switches 516 may be tri-state switches to facilitate input and output functions.

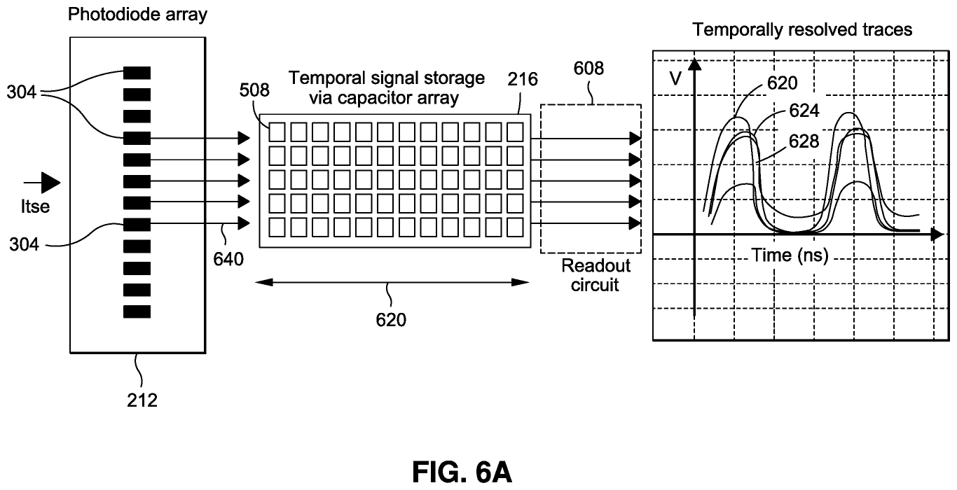

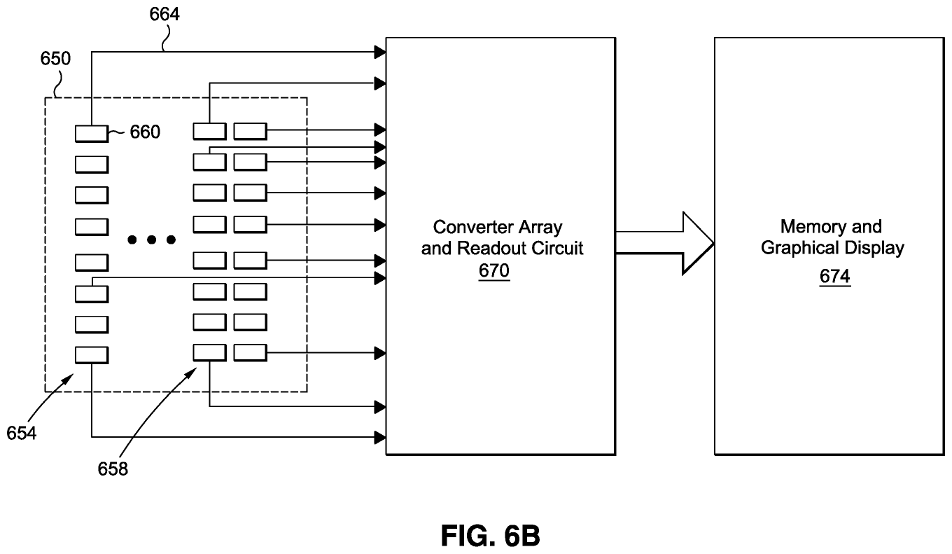

FIG. 6A illustrates a generalized diagram of a solid-state streak camera and the resulting data. As shown the array 212 is composed of numerous photodiodes 304. Upon detection of photos (or other energy types) the photodiodes emit an electrical signal 640 which is provided to the switched capacitor array 216 formed from numerous capacitors 508. As the signal 640 passes from the photodiode 304 along a conductive path, each capacitor that is located along the conductive path captures the charge or signal magnitude at position on the conductive path at which the capacitor attaches to the conductive path. The capacitors record this value. As a result, the position of the capacitor along the conductive path indicates or correlates to the time at which the energy (photon) reached the photodetector. The electrical signals resulting from the first photon interactions will have progressed the furthest down the conductive path while the electrical signal from later photon interactions will not have progressed as far along the conductive path. Consequently, capacitors locate the furthest away from the photodetectors will capture charge representing the first photon interactions while capacitors located closest to the photodetectors will capture charge representing later photon interactions. Thereafter, a readout circuit 608 reads the charge on each capacitor and this resulting data may be stored or plotted.

The plot shown in FIG. 6A shows 5 different lines. For purposes of discussion, plot lines 620, 624, 628 are identified. Each of these lines 620, 624 and 628 correspond to a different photodiode, and the plot 620, 624, 628 represent the voltage or magnitude of the signal 640 from the photodiode 304 in relation to time. Thus, the system can record photon intensity over time. The greater the intensity of photons incident or impacting a photon detector, the greater the magnitude of the resulting electrical signal (charge). It should be noted that this is a significant benefit in that the array 216 of photodiodes record the physical-location at which photon strikes impact the array, while the sample cells (capacitors) record time resolved information at each particular location, such as the time at which the photon strike occurs. Thus, for the 2-dimensional array 216 shown in FIG. 6A, 3-dimensional information is obtained (location in two dimensions coupled with time data regarding the photon strikes).

It is also disclosed that the number of capacitor 508 in the switched capacitor array 216 can be increased to thereby increase the resolution and time window/length of the data that is used for the plots 620, 624, 628. For example, if the array is set up with ten capacitors per photodiode conductive path, then ten data points would be collected. However, the number of capacitors could be increased to 100 or 1000 or more, thereby significantly increasing the resolution of the collected data. It is contemplated that sample lengths of 1024, 2048, and 4096 may be used and in future embodiment sample lengths of 8192, 16384 up to millions of cells are possible. The arrow 620 shows that the number of capacitors may be expanded to increase the resolution (increase the number of data points or data captured in a time period. Or the location of capacitors, or length of the conductive path may change to increase or decrease resolution or time period over which the detector captures data.

It is also disclosed that the array may have any number of photodiodes. Some arrays may have only one photodiode while other one-dimensional arrays could have hundreds or thousands of photodiodes. It is contemplated that each photodiode would have an associated conductive path with associated capacitors. Each photodiode would collect data.

It is further contemplated that the photodiode array may be two dimensional. FIG. 6B illustrates an exemplary two-dimensional photodiode array with associated read-out circuit. In this embodiment, numerous photodiodes 660 are arranged in columns, such as a first column 654 and a second column 658. Although shown in rows and columns it is contemplated that the photodiode could be arranged in any pattern, such as circular or grid array. The photodiodes 660 have an electrical connection 664 which conducts an electrical signal to a switched capacitor array and readout circuit 670. Each photodiode 660 would have an electrical conductor that connects to the switched capacitor array and readout circuit 670, although due to space limitations in FIG. 6B only certain connections are shown.

The output of the switched capacitor array and readout circuit 670 is provided to a memory and graphical display 674. The switched capacitor array and readout circuit 670, and the memory and graphical display 674 operate as described above and hence are not discussed in detail in connection with FIG. 6B.

Forming the photodiode array as a two-dimensional array has the benefit of capturing more data. In addition, the data represents in two dimensions the location of photon impacts on the photodiode array. In addition, the amplitude of the incident photon radiation is recorded over time for each location via the capacitor array associated with that pixel location in the 2D array along the conductive path associated with each photodiode. This potentially provides significantly more information than prior art tube based streak cameras.

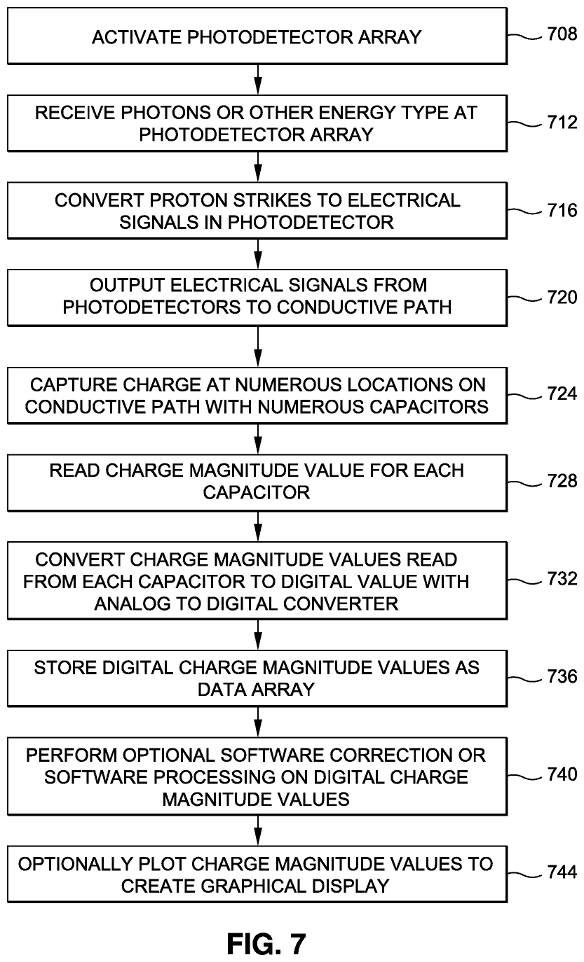

FIG. 7 illustrates an example flow diagram of an example method of operation. This is but one example embodiment, and as such other methods of operation are possible which do not depart from the claims. In this example method of operation, at a step 708 the system activates the photodetector array so that is ready to receive and record the received energy, such as photons or x-rays. The photodetectors may be configured and built to detect different energy sources. In this embodiment photons are detected, but in other embodiments other energy types may be detected. Once an event occurs that causes the photons to interact with the photodetectors, the photodetectors generate electrical signals. This occurs at 716. The intensity or number of photons that interact with a detector in the photodetector array determine the magnitude of the electrical signal.

Next, at a step 720 the system outputs or provides the electrical signals from the photodetectors to a conductive path. The conductive path has numerous capacitors connected to and spaced along the conductive path as described above. At a step 724, the capacitors capture the charge that is on the conductive path at the location where the capacitor connects to the conductive path. As the charge is on the conductive path, capacitors capture and hold this charge.

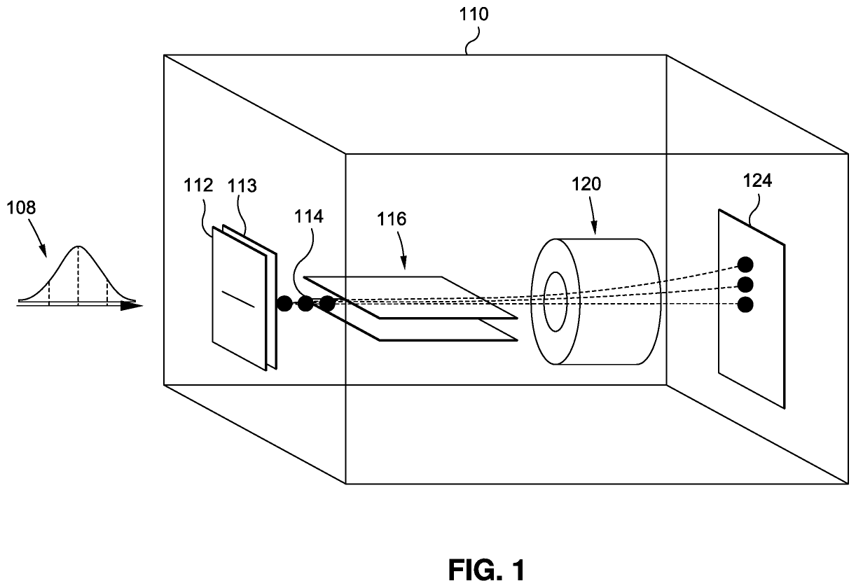

At a step 728, the system reads the charge magnitude that was captured on each capacitor and, at a step 732, analog to digital converters convert the charge magnitude to digital values. This digital data represents the capacitor charge, which represents the incident photon radiation on the photodetectors. At a step 736, digital charge magnitude data is stored as a data array. The data array may have dimensions that represent or is the same ratio as the photodiode array and the data in the data array represents the incident photons on the photodiodes over time. At a step 740 the system optionally performs software correction or other processing on the digital charge magnitude values. This may occur in the system shown in FIGS. 1 and 4 or may be performed in a separate computer or computing system. At a step 744, the system may also optionally graphically plot the signal magnitudes of the electrical signal over time, which represents a plot of the incident photon radiation on the photodiodes over time.

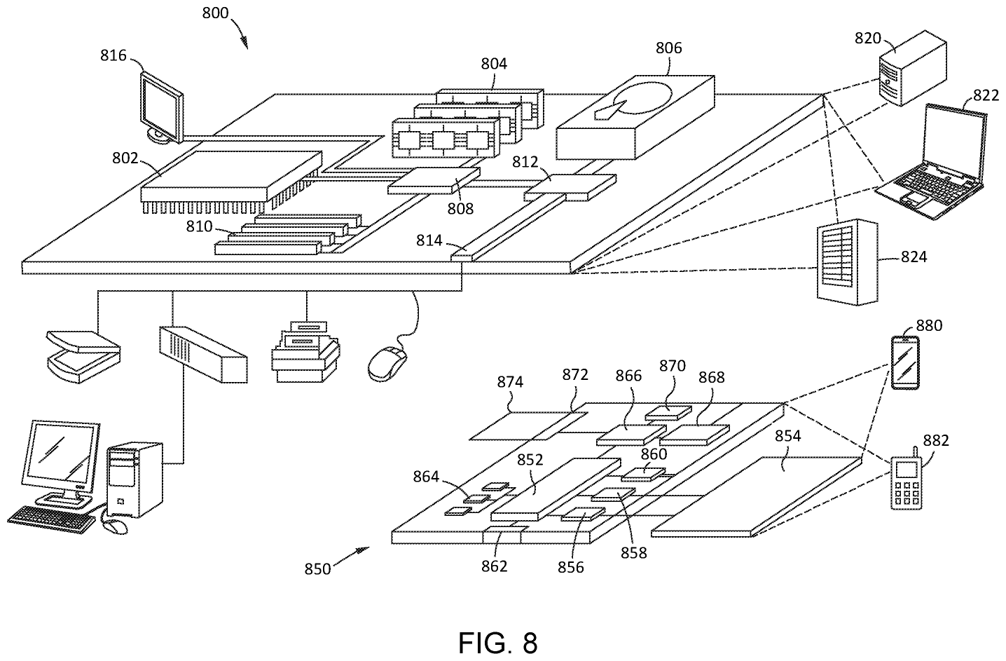

FIG. 8 is a schematic of a computing or mobile device, or server, such as one of the devices described above, according to one exemplary embodiment. FIG. 7 shows an example of a computing device 800 and a mobile computing device 850, which may be used with the techniques described here. Computing device 800 is intended to represent various forms of digital computers, such as laptops, desktops, workstations, personal digital assistants, servers, blade servers, mainframes, and other appropriate computers. Computing device 850 is intended to represent various forms of mobile devices, such as personal digital assistants, cellular telephones, smart phones, and other similar computing devices. The components shown here, their connections and relationships, and their functions, are meant to be exemplary only, and are not meant to limit the implementations described and/or claimed in this document.

Computing device 800 includes a processor 802, memory 804, a storage device 806, a high-speed interface or controller 808 connecting to memory 804 and high-speed expansion ports 810, and a low-speed interface or controller 812 connecting to low-speed bus 814 and storage device 806. Each of the components 802, 804, 806, 808, 810, and 812, are interconnected using various busses, and may be mounted on a common motherboard or in other manners as appropriate. The processor 802 can process instructions for execution within the computing device 800, including instructions stored in the memory 804 or on the storage device 806 to display graphical information for a GUI on an external input/output device, such as display 816 coupled to high-speed controller 808. In other implementations, multiple processors and/or multiple buses may be used, as appropriate, along with multiple memories and types of memory. Also, multiple computing devices 800 may be connected, with each device providing portions of the necessary operations (e.g., as a server bank, a group of blade servers, or a multi-processor system).

The memory 804 stores information within the computing device 800. In one implementation, the memory 804 is a volatile memory unit or units. In another implementation, the memory 804 is a non-volatile memory unit or units. The memory 804 may also be another form of computer-readable medium, such as a magnetic or optical disk.

The storage device 806 is capable of providing mass storage for the computing device 800. In one implementation, the storage device 806 may be or contain a computer-readable medium, such as a hard disk device, an optical disk device, or a tape device, a flash memory or other similar solid-state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 804, the storage device 806, or memory on processor 802.

The high-speed controller 808 manages bandwidth-intensive operations for the computing device 800, while the low-speed controller 812 manages lower bandwidth-intensive operations. Such allocation of functions is exemplary only. In one implementation, the high-speed controller 808 is coupled to memory 804, display 816 (e.g., through a graphics processor or accelerator), and to high-speed expansion ports 810, which may accept various expansion cards (not shown). In the implementation, low-speed controller 812 is coupled to storage device 806 and low-speed bus 814. The low-speed bus 814, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 800 may be implemented in a number of different forms, as shown in the figure. For example, it may be implemented as a standard server 820, or multiple times in a group of such servers. It may also be implemented as part of a rack server system 824. In addition, it may be implemented in a personal computer such as a laptop computer 822. Alternatively, components from computing device 800 may be combined with other components in a mobile device (not shown), such as device 850. Each of such devices may contain one or more of computing device 800, 850, and an entire system may be made up of multiple computing devices 800, 850 communicating with each other.

Computing device 850 includes a processor 852, memory 864, an input/output device such as a display 854, a communication interface 866, and a transceiver 868, among other components. The device 850 may also be provided with a storage device, such as a micro-drive or other device, to provide additional storage. Each of the components 850, 852, 864, 854, 866, and 868, are interconnected using various buses, and several of the components may be mounted on a common motherboard or in other manners as appropriate.

The processor 852 can execute instructions within the computing device 850, including instructions stored in the memory 864. The processor may be implemented as a chipset of chips that include separate and multiple analog and digital processors. The processor may provide, for example, for coordination of the other components of the device 850, such as control of user interfaces, applications run by device 850, and wireless communication by device 850.

Processor 852 may communicate with a user through control interface 858 and display interface 856 coupled to a display 854. The display 854 may be, for example, a TFT LCD (Thin-Film-Transistor Liquid Crystal Display) or an OLED (Organic Light Emitting Diode) display, or other appropriate display technology. The display interface 856 may comprise appropriate circuitry for driving the display 854 to present graphical and other information to a user. The control interface 858 may receive commands from a user and convert them for submission to the processor 852. In addition, an external interface 862 may be provide in communication with processor 852, to enable near area communication of device 850 with other devices. External interface 862 may provide, for example, for wired communication in some implementations, or for wireless communication in other implementations, and multiple interfaces may also be used.

The memory 864 stores information within the computing device 850. The memory 864 can be implemented as one or more of a computer-readable medium or media, a volatile memory unit or units, or a non-volatile memory unit or units. Expansion memory 874 may also be provided and connected to device 850 through expansion interface 872, which may include, for example, a SIMM (Single In Line Memory Module) card interface. Such expansion memory 874 may provide extra storage space for device 850, or may also store applications or other information for device 850. Specifically, expansion memory 874 may include instructions to carry out or supplement the processes described above, and may include secure information also. Thus, for example, expansion memory 874 may be provide as a security module for device 850, and may be programmed with instructions that permit secure use of device 850. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 864, expansion memory 874, or memory on processor 852, that may be received, for example, over transceiver 868 or external interface 862.

Device 850 may communicate wirelessly through communication interface 866, which may include digital signal processing circuitry where necessary. Communication interface 866 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 868. In addition, short-range communication may occur, such as using a Bluetooth, Wifi, or other such transceiver (not shown). In addition, GPS (Global Positioning system) receiver module 870 may provide additional navigation- and location-related wireless data to device 850, which may be used as appropriate by applications running on device 850.

Device 850 may also communicate audibly using audio codec 860, which may receive spoken information from a user and convert it to usable digital information. Audio codec 860 may likewise generate audible sound for a user, such as through a speaker, e.g., in a handset of device 850. Such sound may include sound from voice telephone calls, may include recorded sound (e.g., voice messages, music files, etc.) and may also include sound generated by applications operating on device 850.

The computing device 850 may be implemented in a number of different forms, as shown in the figure. For example, it may be implemented as a cellular telephone 880. It may also be implemented as part of a smart phone 882, personal digital assistant, a computer tablet, or other similar mobile device.

Thus, various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a computer having a display device (e.g., a CRT (cathode ray tube) or LCD (liquid crystal display) monitor) for displaying information to the user and a keyboard and a pointing device (e.g., a mouse or a trackball) by which the user can provide input to the computer. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system (e.g., computing device 800 and/or 850) that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet.

The computing system can include clients and servers. A client and server are generally remote from each other and typically interact through a communication network. The relationship of client and server arises by virtue of computer programs running on the respective computers and having a client-server relationship to each other.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A solid-state streak camera comprising:
a photodetector array, comprising one or more photodetectors, configured to detect energy on the photodetector and generate an electrical signal responsive thereto;
a sample cell module configured to receive and sample the electrical signal as the electrical signal is on the conductive path to create sample values;
analog to digital converters configured to convert the sample values to a digital sample values;
memory configured to store the digital sample values as data, the data representing the energy on the photodetector.

2. The camera of claim 1 wherein the energy is from one of the following energy types: photons, x-rays, or infrared rays.

3. The camera of claim 1 wherein the array is a one-dimensional array.

4. The camera of claim 1 wherein the array is a two-dimensional array.

5. The camera of claim 1 wherein the sample cell module comprises a conductive path with capacitors spaced along the conductive path at connection points, the capacitors configured to store the charge existing on the conductive path at the connection points at a sampling time.

6. The camera of claim 1 wherein the data is stored as a data array that relates to the photodetector array size.

7. The camera of claim 1 wherein the sample values captured from the electrical signal on the conductive path represents energy incident on the photodetector over time.

8. The camera of claim 1 wherein the photodetectors comprise photodiodes.

9. A solid-state streak camera comprising:
photodetectors configured to receive energy from an event and convert the energy to an electrical signal;
a conductive path configured to receive the electrical signal;
two or more capacitors spaced along the conductive path, the capacitors configure to accept and hold capacitor charge, the capacitor charge representing the energy from the event received by the photodetectors and a location of the capacitors along the conductive path correlates to time of receipt of the energy on the photodetector;
analog to digital converters configured to convert the capacitor charge to digital values that represent the energy received by the photodetectors over time;
memory configured to store the digital values as data associated with the photodetector that generated the data.

10. The camera of claim 9 wherein the energy is one of the following energy types: photons, x-rays, or infrared rays.

11. The camera of claim 9 wherein the photodetectors are arranged as a two-dimensional array.

12. The camera of claim 9 wherein one or more switches are associated with each capacitor to selectively connect and disconnect the capacitor form the conductive path.

13. The camera of claim 9 wherein the data is stored as a data array that relates to an arrangement of the photodetectors.

14. The camera of claim 9 wherein the photodetectors comprise photodiodes.

15. A method for detecting and recording emitted energy, over time, from an event, the method comprising:
positioning a photodetector array to receive energy from an event, the photodetector array comprising multiple photodetectors;
receiving energy at the photodetectors that form the photodetector array;
for photodetectors receiving energy, converting the energy received during a time period to a corresponding electrical signal which represents the energy received over time;
presenting the electrical signal on a conductive path, the conductive path having capacitors connected along the conductive path and configured to capture a charge value with the capacitors at the capacitor's points of connection to the conductive path;
capturing the charge value on the conductive path with the capacitors, the position of the capacitor related to time at which the energy was received at the photodetector;
converting the charge value on the capacitors to digital values; and
storing the digital values in a memory.

16. The method of claim 15 wherein the photodetectors are photodiodes.

17. The method of claim 15 wherein the energy is one of following types of energy: photons, x-rays, infrared.

18. The method of claim 15 wherein photodetector array is a two-dimensional array.

19. The method of claim 15 further comprising one or more switches configured to selectively connect and disconnect the capacitor from the conductive path.
